(19) United States
(12) Patent Application Publication
(10) Pub. No.: US 2007/0013038 A1
(43) Pub. Date: Jan. 18, 2007

(54) Semiconductor package having pre-plated leads and method of manufacturing the same

(75) Inventor: Jun-Young Yang, Kyunggi-Do (KR)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/179,475

(22) Filed: Jul. 13, 2005

(51) Int. Cl. H01L 23/495

(52) U.S. Cl. 257/666

(57) ABSTRACT

A quad flat non-lead (QFN) package at least comprises a die, a lead frame and a molding compound. The lead frame comprises a plurality of L-shaped leads for electrically connecting the die. Two pre-plated conductive layers, formed on a bottom portion and a top portion of each L-shaped lead, are exposed to a bottom surface and a top surface of the package, respectively. The molding compound is formed for encapsulating the die and the L-shaped leads.

### BACKGROUND OF THE INVENTION

1. Field of the Invention

The invention relates in general to a semiconductor package having pre-plated leads and method of manufacturing the same, and more particularly to the QFN (Quad Flat Non-Lead) package having pre-plated leads and method of manufacturing the same.

2. Description of the Related Art

In the recent years, the electronic devices, especially the portable products (e.g. digital mobile phone, digital camera and personal digital assistant), have been widely used. To meet the demand of the growing market, the semiconductor manufacturers face many challenges in supplying suitable electronic device of the electronic devices. One of the challenges is to provide the customers with a thin, light, but powerful device. Also, this device is much attractive if it is cost is much lower. Thus, a very thin, light and low-cost semiconductor package, so called as “Quad Flat Non-Lead” (QFN) package, has been developed to operate the electronic device.

FIG. 1 is a cross-sectional view of a conventional QFN package. The QFN package 10 comprises a die (i.e. semiconductor chip) 11, and a lead frame having a die paddle 12 for carrying the die 11 and the leads 13 surrounding the die 11. The lead frame is conventionally made of conductive material, such as copper, copper alloy or iron-nickel alloy. The die paddle 12 is generally a flat rectangular or square shape. The die 11 is positioned at the die paddle 12, typically using an adhesive material (such as epoxy resin), and is electrically connected to the leads 13 through the wires 15. Also, a molding compound 17, made of a nonconductive sealing material, for example, epoxy resin, is formed for encapsulating the die 11, the die paddle 12, the leads 13 and the wires 15. The lead 13, having the extending portion on which the wire 15 is bonded, is configured to increase the contact area between the lead 13 and the molding compound 17.

According to FIG. 1, the bottom surface 121 of the die paddle 12 is exposed to the environment for increasing the heat dissipation capability of the package 10. The bottom surface 121 of the die paddle 12 could be coated with a corrosion-resisting material. Also, the bottom portion 131, the top portion 132 and the side portion 133 of the lead 13 are exposed to the bottom surface, the top surface and the sides of the package 10, respectively. After the package 10 is disposed to a printed circuit board (PCB) substrate (not shown in FIG. 1), those exposed portions of the leads 13 are used to electrically access the die 11.

For providing more functions for the applied electrical device, two, three even more packages are required in an electrical device. FIG. 2 is a cross-sectional view showing two packages of FIG. 1 being stacked. The first package 10a is stacked on the second package 10b, and the second package 10b is attached to a PCB substrate 20. The solder pads 24a can be used to physically attach the first package 10a to the second package 10b. Similarly, the solder pads 24b can be used to physically attach the second package 10b to the PCB substrate 20.

However, the conventional QFN package 10 as described above requires two-side half etching to configure the lead frame, so as to increase the cost of process. Also, a lead frame with a certain thickness should be used for perform two-side half etching, and the overall thickness of the package is subjected to the height of the lead frame. Moreover, the isolated vacuum block is required for preventing the bouncing effect so as to securely and precisely perform the wire-bonding process. Also, an adhesive material is needed to attach the die 11 on the die paddle 12. Also, the thermal expansion coefficient of the die paddle 12 is different from that of the die 11, thereby causing the problem of delamination or mismatch during the manufacture of the package 10. Additionally, the exposed surfaces (i.e. the bottom portion 131, the top portion 132 and the side portion 133) of the lead could be damaged (e.g. due to the moisture corrosion), and has the effect on the conductivity of the lead, especially on the packages of the stacked structure. The extra steps are required after the package is completed to improve the electrical connection between the packages, thereby increasing the cost of production.

### SUMMARY OF THE INVENTION

It is therefore an object of the invention to provide a semiconductor package, particularly a QFN (Quad Flat Non-Lead) package, having pre-plated leads and method of manufacturing the same. With the pre-plated leads, the package having good conductivity is easy to accessible. Also, high production yield can be achieved due to the pre-plated step of the method, and the production cost is decreased by applying the simple method of manufacturing the package of the invention.

The invention achieves the objects by providing a quad flat non-lead (QFN) package at least comprising a die, a lead frame and a molding compound. The lead frame comprises a plurality of L-shaped leads for electrically connecting the die. Two pre-plated conductive layers, formed on a bottom portion and a top portion of each L-shaped lead, are exposed to a bottom surface and a top surface of the package, respectively. The molding compound is formed for encapsulating the die and the L-shaped leads.

The invention achieves the objects by providing a method of manufacturing a quad flat non-lead (QFN) package. First, a lead frame having a plurality of L-shaped leads is provided. Each L-shaped lead has a bottom portion and a top portion. Then, the lead frame is plated to form two pre-plated conductive layers on the bottom portion and the top portion of each L-shaped lead. Next, a die is disposed corresponding the L-shaped leads, and electrically connected to the L-shaped leads. A molding compound is applied to encapsulate the die and the L-shaped leads. Afterward, the pre-plated conductive layers, formed on the bottom portion and the top portion of each L-shaped lead, are exposed to a bottom surface and a top surface of the package, respectively.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (prior art) is a cross-sectional view of a conventional QFN package.

FIG. 2 (prior art) is a cross-sectional view showing two packages of FIG. 1 being stacked.

FIG. 3 is a cross-sectional view of a single QFN package according to the first embodiment of the invention.

FIG. 4A˜FIG. 4E schematically illustrate a method of manufacturing the package having pre-plated leads according to the first embodiment of the invention.

FIG. 5A and FIG. 5B are cross-sectional views of two QFN packages of the stacked structures according to the first embodiment of the invention.

FIG. 5C and FIG. 5D are cross-sectional views of three QFN packages of the stacked structures according to the first embodiment of the invention.

FIG. 6 is a cross-sectional view of a single QFN package according to the second embodiment of the invention.

FIG. 7A and FIG. 7B are cross-sectional views of two QFN packages of the stacked structures according to the second embodiment of the invention.

FIG. 7C and FIG. 7D are cross-sectional views of three QFN packages of the stacked structures according to the second embodiment of the invention.

FIG. 8 is a cross-sectional view of a single QFN package according to the third embodiment of the invention.

FIG. 9A and FIG. 9B are cross-sectional views of two QFN packages of the stacked structures according to the third embodiment of the invention.

FIG. 9C and FIG. 9D are cross-sectional views of three QFN packages of the stacked structures according to the third embodiment of the invention.

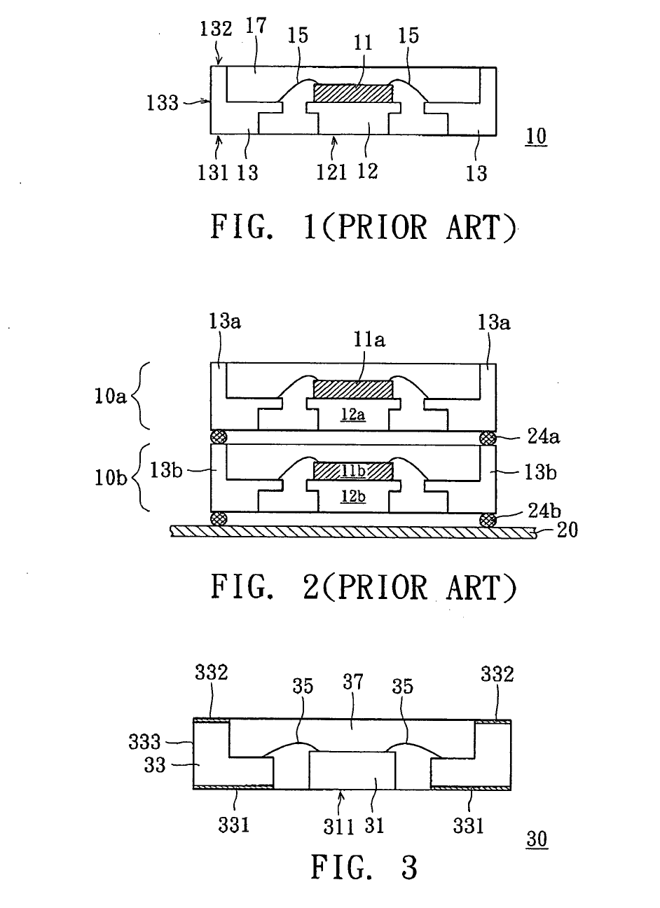

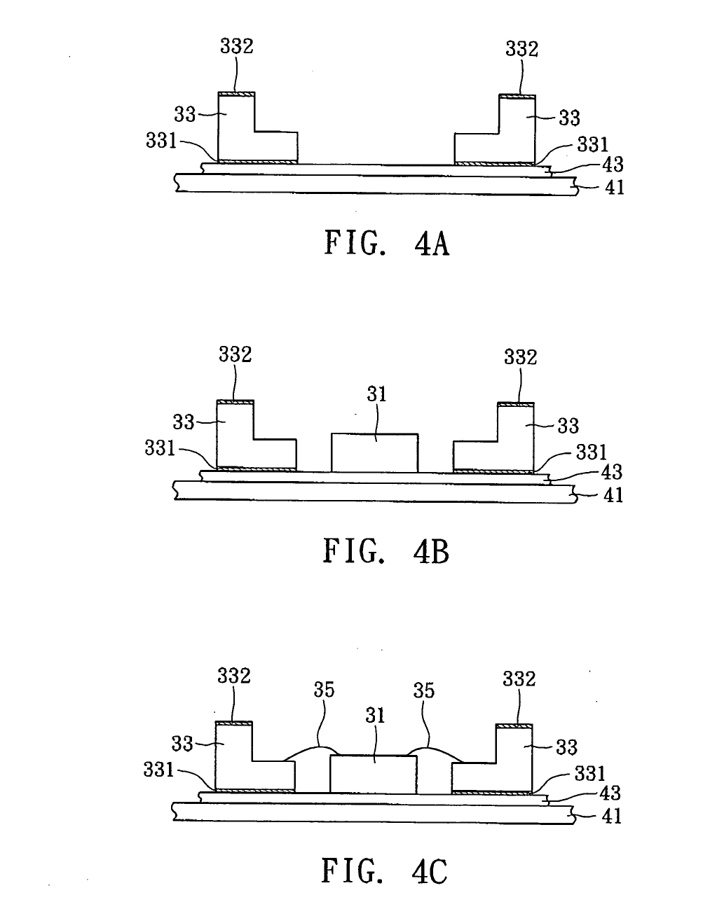

### DETAILED DESCRIPTION OF THE INVENTION

The invention provides a semiconductor package, particularly a QFN (Quad Flat Non-Lead) package, having pre-plated leads and method of manufacturing the same. Also, the package constructed according to the invention is thinner than the conventional package. Three embodiments are taken for describing the QFN packages having pre-plated leads and method of manufacturing the same.

The embodiments disclosed herein are for illustrating the invention, but not for limiting the scope of the invention. Additionally, the drawings used for illustrating the embodiments of the invention only show the major characteristic parts in order to avoid obscuring the invention. Accordingly, the specification and the drawings are to be regard as an illustrative sense rather than a restrictive sense.

### First Embodiment

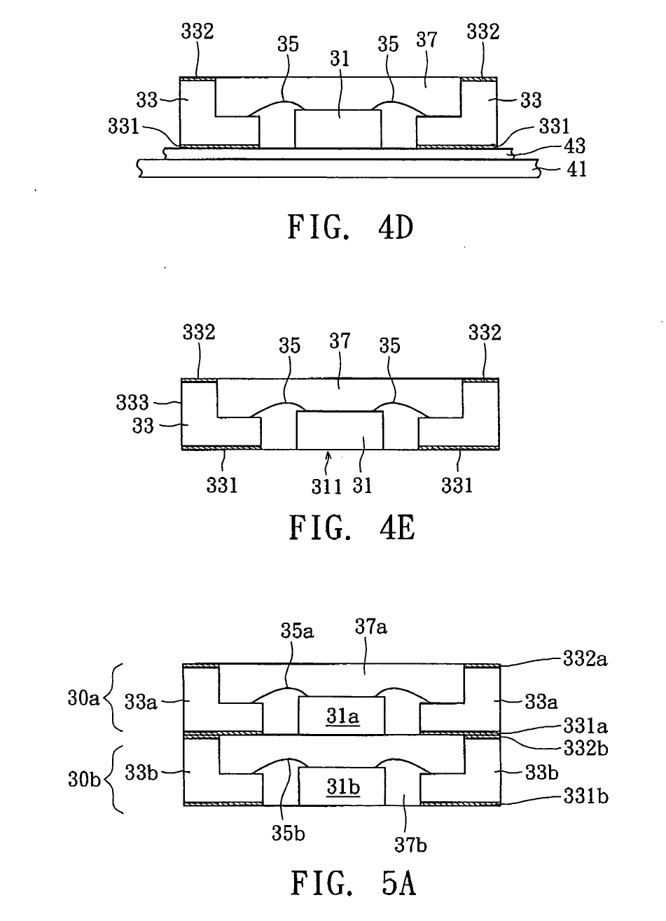

FIG. 3 is a cross-sectional view of a single QFN package according to the first embodiment of the invention. According to the first embodiment of the invention, the QFN package 20 comprises a die (i.e. semiconductor chip) 31, and a lead frame having the leads 33 surrounding the die 31. The lead frame, made of conductive material such as copper, copper alloy or iron-nickel alloy, is plated, so as to form the pre-plated conductive layers 331 and 332 respectively on the bottom portion and the top portion of the leads 33. The material of the pre-plated conductive layers 331 and 332 could be nickel (Ni), palladium (Pd), silver (Ag), or the alloy of the combination. Also, several bonding pads and bonding terminals (not shown) are formed on the die 31 and the leads 33, respectively. Each wire 35 connects the bonding pad of the die 31 and the bonding terminal of the lead 33 for the purpose of electrical connection of the die 31 and the lead 33. Also, a molding compound 37, made of a nonconductive sealing material, for example, epoxy resin, is formed for encapsulating the die 31, the leads 33 and the wires 35.

According to FIG. 3, the bottom surface 311 of the die 31 is exposed to the environment. The pre-plated conductive layers 331, 332 (i.e. formed on the bottom portion and the top portion of the lead 33), and the side portion 333 of the lead 33 are exposed to the bottom surface, the top surface and the sides of the package 30, respectively. After the package 30 is disposed to a printed circuit board (PCB) substrate (not shown in FIG. 3), the pre-plated conductive layers 331, 332 of the leads 33 are used to electrically access the die 31.

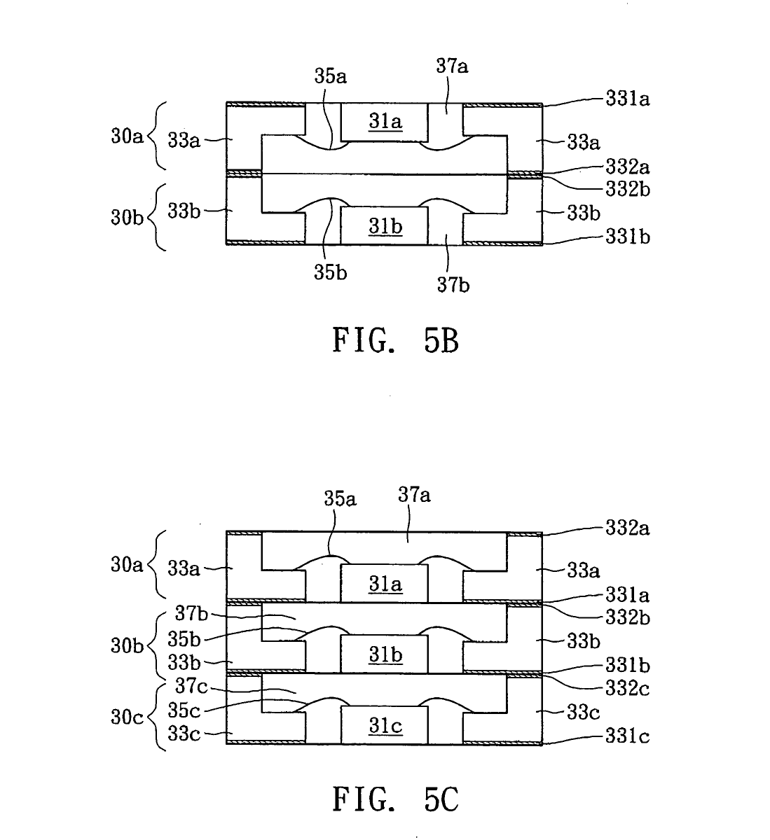

FIG. 4A˜FIG. 4E schematically illustrate a method of manufacturing the package having pre-plated leads according to the first embodiment of the invention. First, a supporting base 41 is provided, and an adhesion tape 43 is attached thereon. A lead frame having several L-shaped leads 33 is provided, and each lead has a bottom portion and a top portion. The lead frame is plated to form the pre-plated conductive layers 331 and 332 on the bottom portion and the top portion of the lead 33. The material of the pre-plated conductive layers 331 and 332 could be nickel (Ni), palladium (Pd), silver (Ag), or the alloy of the combination. Then, the lead frame having pre-plated leads is disposed on the adhesion tape 43, as shown in FIG. 4A. Next, a die 31 is disposed on the adhesion tape 43 and surrounded by the leads 33, as shown in FIG. 4B. Then, the die 31 and the leads 33 are electrically connected through the wires 35, as shown in FIG. 4C. A molding compound 37 (e.g. epoxy resin) is formed for encapsulating the die 31, the leads 33 and the wires 35, as shown in FIG. 4D. Finally, the supporting base 41 and the adhesion tape 43 are removed to expose the bottom surface 311 of the die 31, as shown in FIG. 4E.

Compared to the conventional structure, the QFN package of the invention has several advantages. The QFN package according to the embodiment of the invention requires only one-side half etching to configure the lead frame, so as to decrease the cost of process. Also, without the use of die paddle, the thickness of the package can be decreased, and it is no need to use the adhesive material for attaching the die on the die paddle. Also, the problem of delamination or mismatch between the die paddle and the die (caused by the difference of the thermal expansion coefficients of the die paddle and the die) during the manufacture of the package can be prevented. Additionally, by applied the lead 33 having the L-shaped cross-section as illustrated in the embodiments of the invention, it easy to perform the wire bonding procedures without considering the bouncing effect on wire bonding. Moreover, with the leads having the pre-plated conductive layers, the electrical connection between the packages (or between the package and the PCB substrate) can be successfully achieved. Once the package is completely manufactured, the packages can be stacked and electrically connected through the pre-plated conductive layers. No extra step is required to repair or improve the electrical connection after the package is completed, thereby decreasing the cost of production.

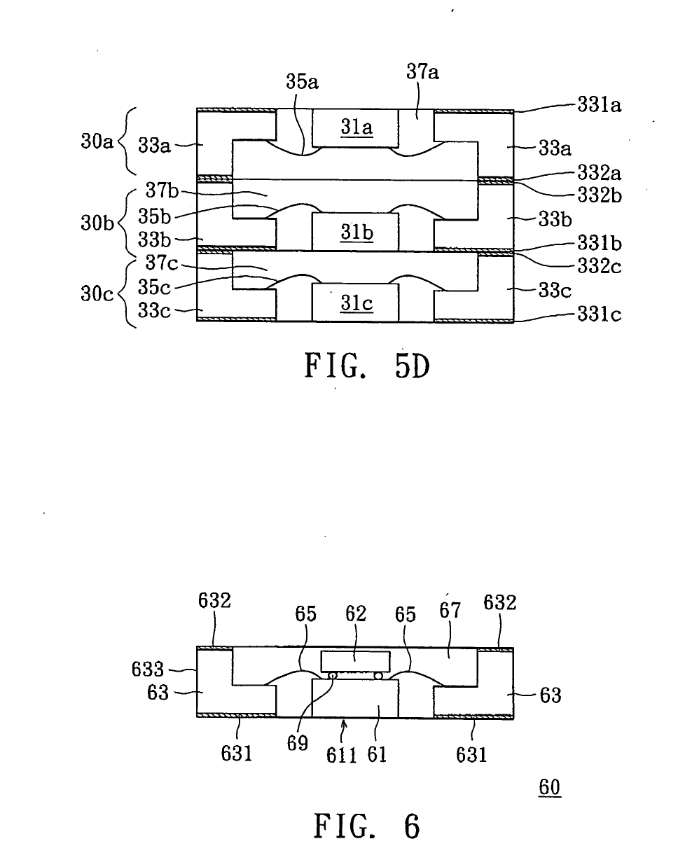

Moreover, the package 30 as illustrated in FIG. 3 could be stacked in many ways. FIG. 5A and FIG. 5B are cross-sectional views of two QFN packages of the stacked structures according to the first embodiment of the invention. In FIG. 5A and FIG. 5B, the first package 30a is stacked on the second package 30b. Also, the second package 30b could be attached to a PCB substrate (not shown). As shown in FIG. 5A, the pre-plated conductive layers 331a of the leads 33a connect the pre-plated conductive layers 332b of the leads 33b. The difference between the stacked structure of FIG. 5A and FIG. 5B is the inverting disposition of the first package 30a; thus, the pre-plated conductive layers 332a of the leads 33a connect the pre-plated conductive layers 332b of the leads 33b, as shown in FIG. 5B.

FIG. 5C and FIG. 5D are cross-sectional views of three QFN packages of the stacked structures according to the first embodiment of the invention. The first package 30a is stacked on the second package 30b, and the second package 30b is stacked on the third package 30c, as illustrate in FIG. 5C and FIG. 5D. Similarly, the difference between the stacked structure of FIG. 5C and FIG. 5D is the inverting disposition of the first package 30a.

### Second Embodiment

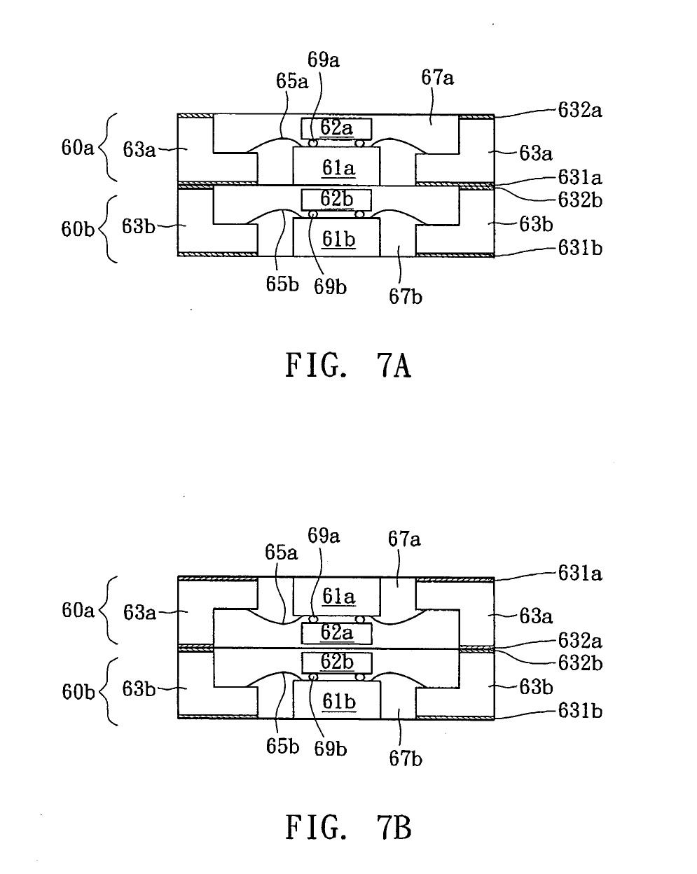

FIG. 6 is a cross-sectional view of a single QFN package according to the second embodiment of the invention. The difference between the first (FIG. 3) and second (FIG. 6) embodiments is the die number applied in a single package. In the second embodiment, the QFN package 60 comprises a first die (i.e. mother chip) 61, a second die (i.e. daughter chip) 62 and a lead frame having the leads 63 surrounding the first die 61 and the second die 62. In the practical application, the first die 61 could be DDR, SRAM or Flash, and the second die 62 could be IPC, IPD or controller. According to the second embodiment, the second die 62 is attached to and electrically connected to the first die 61 through the conductive bumps 69 (such as the solder balls).

Also, the lead frame is plated to form the pre-plated conductive layers 631 and 632 respectively on the bottom portion and the top portion of the leads 63. The material of the pre-plated conductive layers 631 and 632 could be nickel (Ni), palladium (Pd), silver (Ag), or the alloy of the combination. The wires 65 electrically connect the first die 61 and the leads 63. A molding compound 67 (e.g. epoxy resin) is formed for encapsulating the first die 61, the second die 62, the leads 63 and the wires 65.

The method of manufacturing the package having pre-plated leads according to the second embodiment of the invention is similar as the method described in FIG. 4A˜FIG. 4E, except step of the second die 62 bonded to the first die 61 by the conductive bumps 69 is required before step of applying the molding compound 67.

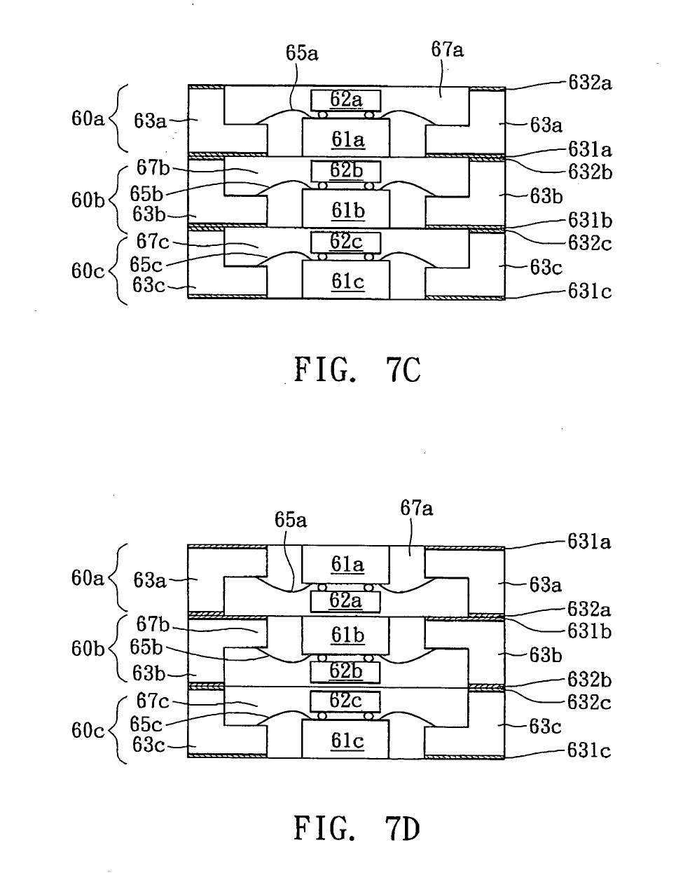

Moreover, the package 60 as illustrated in FIG. 6 could be stacked in many ways. FIG. 7A and FIG. 7B are cross-sectional views of two QFN packages of the stacked structures according to the second embodiment of the invention. FIG. 7C and FIG. 7D are cross-sectional views of three QFN packages of the stacked structures according to the second embodiment of the invention. In FIG. 7A and FIG. 7B, the first package 60a is stacked on the second package 60b. In FIG. 7C and FIG. 7D, the second package 60a is further stacked on the third package 60c. As shown in FIG. 7B, the first package 60a is inversely disposed on the second package 60b. As shown in FIG. 7D, the first package 60a and the second package 60b are inversely disposed on the third packages 60c. In those stacked structure, the pre-plated conductive layers 631a, 631b, 631c, 632a, 632b and 632c provide a fast accessible way to transmit the electrical signals between the packages.

### Third Embodiment

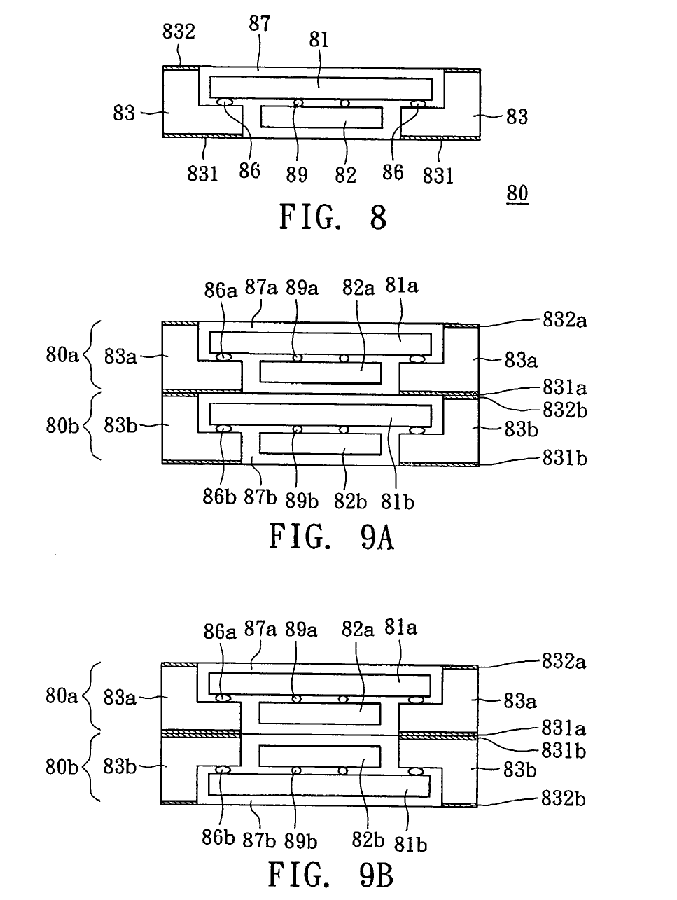

FIG. 8 is a cross-sectional view of a single QFN package according to the third embodiment of the invention. In the third embodiment, the QFN package 80 comprises a first die (i.e. mother chip) 81, a second die (i.e. daughter chip) 82 and a lead frame having the leads 83 surrounding the first die 81 and the second die 82. The difference between the second (FIG. 6) and third (FIG. 8) embodiments is the bonding method between the first die and the leads. According to the third embodiment, the first die 81 is electrically connected to the leads 83 through the first conductive bumps 86, and the second die 82 is electrically connected to the first die 81 through the second conductive bumps 89 (such as the solder balls).

Also, the lead frame is plated to form the pre-plated conductive layers 831 and 832 respectively on the bottom portion and the top portion of the leads 83. The material of the pre-plated conductive layers 631 and 632 could be nickel (Ni), palladium (Pd), silver (Ag), or the alloy of the combination. A molding compound 87 (e.g. epoxy resin) is formed for encapsulating the first die 81, the second die 82, the leads 83, the first conductive bumps 86 and the conductive bumps 89.

The method of manufacturing the package having pre-plated leads according to the third embodiment of the invention is similar as the method described in FIG. 4A˜FIG. 4E, except step of the second die 82 bonded to the first die 81 by the conductive bumps 89 is required before step of applying the molding compound 87.

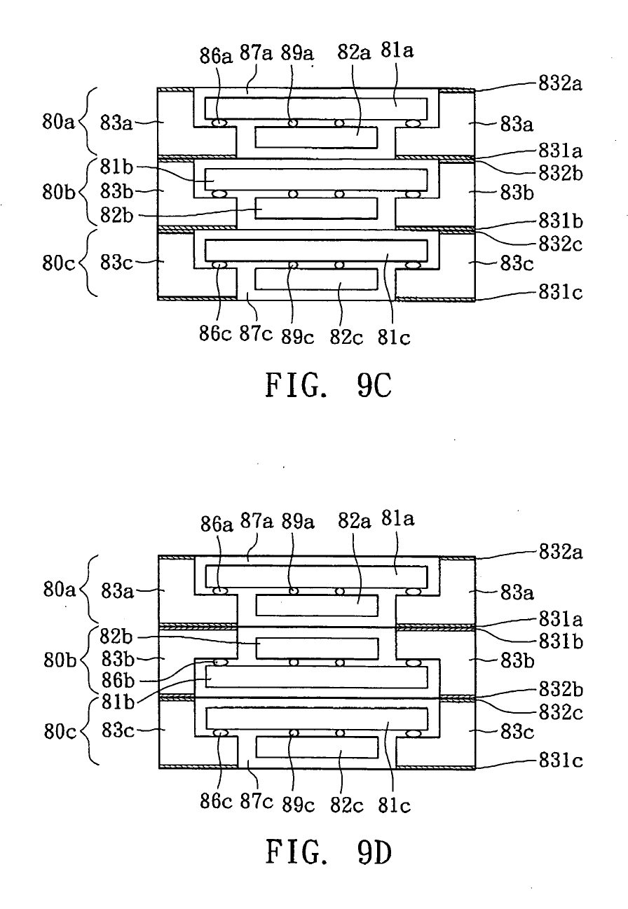

Moreover, the package 80 as illustrated in FIG. 8 could be stacked in many ways. FIG. 9A and FIG. 9B are cross-sectional views of two QFN packages of the stacked structures according to the third embodiment of the invention. FIG. 9C and FIG. 9D are cross-sectional views of three QFN packages of the stacked structures according to the third embodiment of the invention. In FIG. 9A and FIG. 9B, the first package 80a is stacked on the second package 80b. Also, the second package 80b of FIG. 9B is inversely disposed below the first package 80a. In FIG. 9C and FIG. 9D, the second package 80a is further stacked on the third package 80c. Also, the second package 80b of FIG. 9D is inversely disposed on the third package 80c. In those stacked structure, the pre-plated conductive layers 831a, 831b, 831c, 832a, 832b and 832c provide a fast accessible way to transmit the electrical signals between the packages.

According to the aforementioned description, the embodiments of the invention provide many advantages over conventional package technology. For example, the invention provides a thinner, lighter and high-density package. With the pre-plated lead frame, the package manufactured by a simple and low-cost process is highly conductive. Also, the signal transmission between the packages (or between the package and PCB) is easy and fast accessible.

While the invention has been described by way of examples and in terms of the preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A quad flat non-lead (QFN) package, at least comprising:
a die;
a lead frame having a plurality of L-shaped leads for electrically connecting the die, two pre-plated conductive layers formed on a bottom portion and a top portion of each L-shaped lead being exposed to a bottom surface and a top surface of the package, respectively; and
a molding compound, encapsulating the die and the L-shaped leads.

2. The package according to claim 1, wherein the pre-plated conductive layer is made of nickel (Ni), palladium (Pd), silver (Ag) or an alloy thereof.

3. The package according to claim 1 further comprising a plurality of wires for electrically connecting the die and the L-shaped leads.

4. The package according to claim 1 further comprising a plurality of conductive bumps for electrically connecting the die and the L-shaped leads.

5. The package according to claim 1 further comprising another die electrically connected to the die through a plurality of conductive bumps.

6. The package according to claim 5, wherein a plurality of bonding pads are formed on the die, and the die is electrically connecting to another die by the contact between the conductive bumps and the bonding pads.

7. A method of manufacturing a quad flat non-lead (QFN) package, at least comprising steps of:
providing a lead frame having a plurality of L-shaped leads, each L-shaped lead having a bottom portion and a top portion;
plating the lead frame to form two pre-plated conductive layers on the bottom portion and the top portion of each L-shaped lead;
disposed a die corresponding the L-shaped leads;
electrically connecting the die and the L-shaped leads; and
applying a molding compound to encapsulate the die and the L-shaped leads, and the pre-plated conductive layers formed on the bottom portion and the top portion of each L-shaped lead being exposed to a bottom surface and a top surface of the package, respectively.

8. The method according to claim 7, further comprising step of:
providing an adhesion tape for attaching the die and the L-shaped leads.

9. The method according to claim 8, wherein the adhesion tape is removed after the molding compound has been formed for encapsulating the die and the L-shaped leads.

10. The method according to claim 7, further comprising step of:
providing a plurality of wires for electrically connecting the die and the L-shaped leads.

11. The method according to claim 7, further comprising step of:
providing a plurality of conductive bumps for electrically connecting the die and the L-shaped leads.

12. The method according to claim 7, further comprising step of:
providing another die to electrically connect the die in the package through a plurality of conductive bumps.

13. The method according to claim 7, wherein the pre-plated conductive layer is made of nickel (Ni), palladium (Pd), silver (Ag) or an alloy thereof.
